(19) United States
(12) Patent Application Publication
(10) Pub. No.: US 2008/0105542 A1
(43) Pub. Date: May 8, 2008

(54) SYSTEM AND METHOD OF MANUFACTURING SPUTTERING TARGETS

(76) Inventors: Clifford C. Purdy, Reno, NV (US); Gregory M. Howard, Reno, NV (US)

Correspondence Address: IAN F. BURNS & ASSOCIATES, P.O. BOX 71115, RENO, NV, 89570, US

(21) Appl. No.: 11/937,337

(22) Filed: Nov. 8, 2007

Related U.S. Application Data
(60) Provisional application No. 60/864,968, filed on Nov. 8, 2006.

(51) Int. Cl. C23C 14/34

(52) U.S. Cl. 204/298.13

(57) ABSTRACT

A method for manufacturing a sputtering target assembly that is used with a sputtering deposition machine. A molten target material is deposited onto a substrate or backing plate to form a target assembly. The target assembly is heated to approximately the melting point temperature of the target material in order to form an alloy interface layer between the substrate and the target material that improves the bond strength of the target assembly. In one embodiment, the thickness of the alloy interface layer can be controlled by cooling the substrate during the formation of the alloy interface layer.

### CROSS REFERENCE TO RELATED APPLICATIONS

This application claims priority to U.S. provisional patent application Ser. No. 60/864,968, filed 8 Nov. 2006, the contents of which are herein incorporated by reference.

### FIELD OF THE INVENTION

The present invention relates to sputtering target assemblies and other metal articles, as well as methods of making the same. More particularly, the present invention relates to methods to bond various metals together to form bonded sputtering target assemblies and other bonded articles.

### BACKGROUND OF THE INVENTION

In a sputtering process, a target material is subject to bombardment by energetic ions. In a sputtering process using a multi-constituent target, each constituent may sputter at a different rate. Therefore, in order to produce a sputtered film with the constituents in the correct ratio, it is important that the target material have specific proportions of the constituent materials.

Typically, the target material is first formed and then bonded to a backing plate in order to provide the appropriate electrical connections, and any cooling connections, to the target material. It is important that the target material be well bonded to the backing plate to increase conductivity. Methods for bonding the backing plate to the target material include using an adhesive such as by epoxy cement. Other techniques include brazing, diffusion bonding and soldering. However, these methods can provide limitation on the shape of sputter targets produced. Target assemblies bonded using the prior art methods have experienced separation and delamination during use due to differences in thermal expansion between the backing plate and the target material.

### SUMMARY OF ONE EMBODIMENT OF THE INVENTION

Advantages of One or More Embodiments of the Present Invention

The various embodiments of the present invention may, but do not necessarily, achieve one or more of the following advantages:

increased bonding between the target and the backing plate;

reduced delamination between the target and the backing plate or substrate;

increased conductivity between the target and the backing plate;

enhanced operation of the target during sputtering due to the increased bonding between the target and the backing plate;

increased selectivity in the shape of the target assembly;

reduced contamination of the target; and

controlled purity of the target.

These and other advantages may be realized by reference to the remaining portions of the specification, claims, and abstract.

### BRIEF DESCRIPTION OF ONE EMBODIMENT OF THE PRESENT INVENTION

The present invention provides a method of manufacturing a sputtering target. The method includes depositing a target onto a substrate and heating the substrate and the target to approximately a melting temperature of the target. The target and the substrate are cooled such that an alloy interface layer is formed between the substrate and the target.

The present invention also provides a sputtering target assembly. The sputtering target assembly includes a backing plate that has an outer surface and an inner surface. A target has an outer surface and an inner surface. An interface layer is formed between the outer surface of the substrate and the inner surface of the target. The interface layer is an alloy of the substrate and the target.

The above description sets forth, rather broadly, a summary of one embodiment of the present invention so that the detailed description that follows may be better understood and contributions of the present invention to the art may be better appreciated. Some of the embodiments of the present invention may not include all of the features or characteristics listed in the above summary. There are, of course, additional features of the invention that will be described below and will form the subject matter of claims. In this respect, before explaining at least one preferred embodiment of the invention in detail, it is to be understood that the invention is not limited in its application to the details of the construction and to the arrangement of the components set forth in the following description or as illustrated in the drawings. The invention is capable of other embodiments and of being practiced and carried out in various ways. Also, it is to be understood that the phraseology and terminology employed herein are for the purpose of description and should not be regarded as limiting.

### BRIEF DESCRIPTION OF THE DRAWINGS

FIG. 1A is substantially a top view of an embodiment of a mold in accordance with present invention;

FIG. 1B is substantially a side cross-sectional view of the mold of FIG. 1A taken along section line AA;

FIG. 1C is substantially a side cross-sectional view of the mold of FIG. 1A and a backing plate;

FIG. 1D is substantially a side cross-sectional view of the mold of FIG. 1A, a backing plate and a target;

FIG. 1E is substantially a side cross-sectional view of the mold of FIG. 1A, a backing plate and a target inside a furnace;

FIG. 2 is substantially a side cross-sectional view of a sputtering target assembly in accordance with the present invention;

FIG. 3 depicts a flowchart of a method for manufacturing a sputtering target assembly;

FIG. 4 is substantially a top view of an alternative embodiment of a sputtering target assembly in accordance with the present invention;

FIG. 5 is substantially a perspective view of the sputtering target assembly of FIG. 4;

FIG. 6 is substantially a perspective view of an alternative embodiment of a mold in accordance with present invention;

FIG. 7 is substantially a top view of FIG. 4 after processing; and

FIG. 8 is substantially a perspective view of FIG. 5 after processing.

### DESCRIPTION OF CERTAIN EMBODIMENTS OF THE PRESENT INVENTION

In the following detailed description of the preferred embodiments, reference is made to the accompanying drawings, which form a part of this application. The drawings show, by way of illustration, specific embodiments in which the invention may be practiced. It is to be understood that other embodiments may be utilized and structural changes may be made without departing from the scope of the present invention.

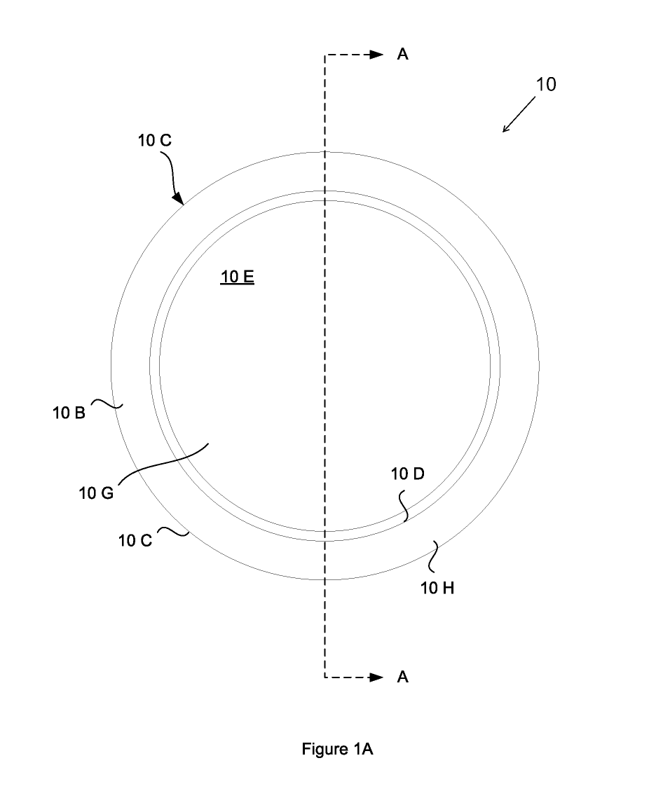

With reference to FIGS. 1A and 1B, there is shown a casting form or mold 10 for receiving a molten alloy. The form 10 may be made from a variety of materials that are adapted to withstand the heat of the casting process and prevent contamination of the sputtering target. In one embodiment, the form 10 may be made from graphite. However the person skilled in the art will readily understand that other materials may be used and will largely be dependent on the types of materials being used for both the target material and the backing plate, as will be described below.

In another embodiment, the target material is cast separately and cooled. The cooling may be performed by blowing a gas, such as Argon, on to the material, directing a moving a liquid through the casting form or in other ways that are known in the art. The target material is then joined to the substrate with Indium or other joining media, such as a conductive elastomer, many of which are well known in the art.

Form 10 may have a round or disc shape. Other shapes may also be used. Form 10 may include a base 10A from which side walls 10B circumferentially extend. Side walls 10B have an outer surface 10C, an inner surface 10D and a top 10H. A bottom wall 10E is located above base 10A and between side walls 10B. Bottom wall 10E and side walls 10B define a cavity 10G.

Turning now to FIG. 1C, in order to produce a sputtering target assembly, a substrate or backing plate 12 is first placed or disposed within the form 10. Backing plate 12 may have the same general shape as form 10. Backing plate 12 may have a top 12A, a bottom 12B and a circumferential side surface 12C. The backing plate 12 may be any suitable material and the person skilled in the art will readily understand that the choice of material will be largely dependent on the target material to be used. Generally, the backing plate 12 is electrically conductive, provides structural strength for supporting the target material and is of a material that does not significantly contaminate the target material.

For clarity in the figures, a small gap is shown between side surface 12C of backing plate 12 and inner surface 10D of form 10. In actual practice, this gap does not exist and backing plate 12 fits tightly into form 10 such that side surface 12C is closely adjacent to and in contact with inner surface 10D.

The backing plate 12 may be machined or cast into any desired shape before it is placed in the form 10. Backing plate 12 may also be formed by melting the molten material of backing plate 12 and casting into form 10. In one embodiment, copper may be used to form backing plate 12.

As shown in FIG. 1D, a target 14 can be formed from a wide variety of materials. In one embodiment target 14 comprises Copper Indium Gallium (CIG), Copper Indium Gallium Selenium (CIGS) or other similar alloys. Target 14 can have a top surface 14A, bottom surface 14B and circumferential side surface 14C. Bottom surface 14B and top 12A are adjacent to and in contact with each other such that an interface 20 is formed.

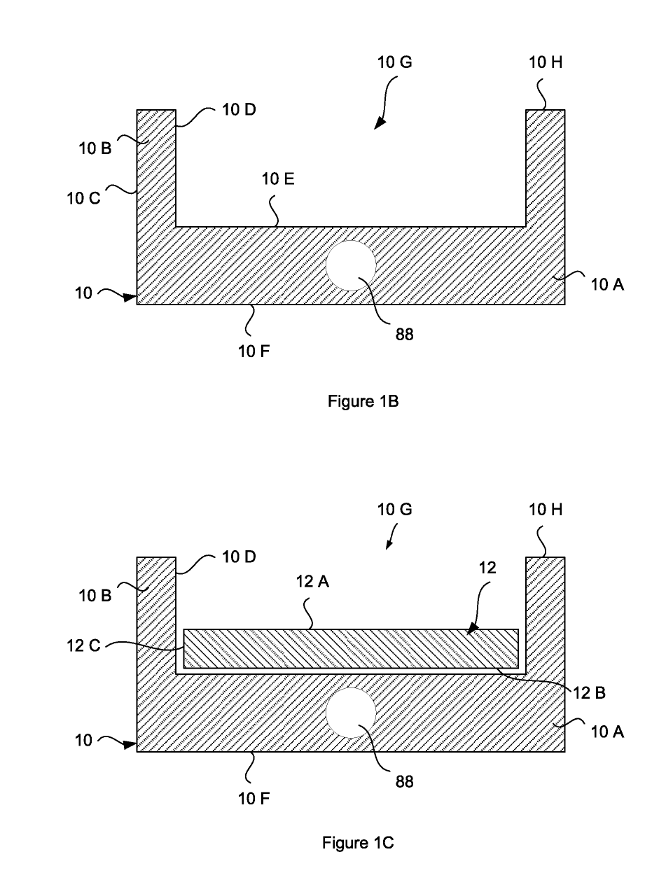

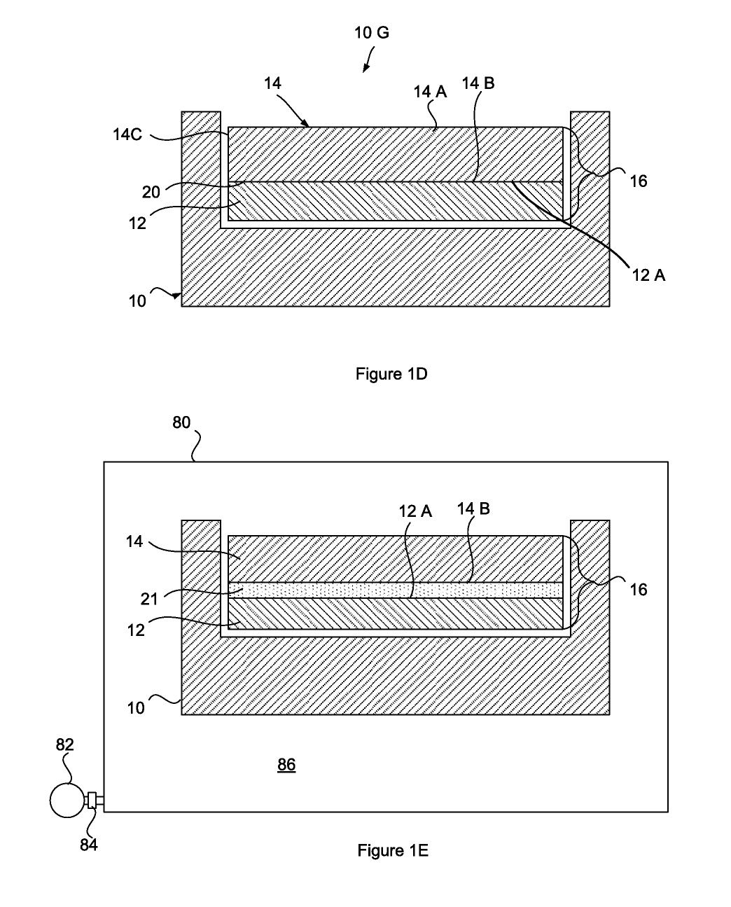

A process for forming a sputtering target assembly 16 will now be described with reference to FIG. 1E, FIG. 2 and the flow chart of method 100 depicted in FIG. 3. Once the backing plate 12 has been placed in the form 10 at step 101, molten target material or target 14 may be poured into the form 10 at step 102. Sputtering target assembly 16 can include backing plate 12 and target 14. The form 10 and the sputtering target assembly 16, including the backing plate 12 and target 14, are then heated to an appropriate temperature at step 103, for example by placing sputtering target assembly 16 into a furnace 80.

In one embodiment, furnace 80 may be connected to a gas source 82 in order to create a desired atmosphere 86 within furnace 80. A valve 84 may regulate the gas source 82 flowing into furnace 80. The gas introduced into furnace 80 may be any desired gas such as an inert gas like argon or nitrogen or a reducing gas such as hydrogen. Gas source 82 may be a mixture of various gases. In one embodiment, the process may be performed in a vacuum so that the risk of contamination from gases is reduced. In this embodiment, a form made of graphite or other suitable material may be used, that includes channels for circulating a cooling liquid so that the form and the target material may be cooled rapidly.

In one embodiment, the temperature to which the sputtering target assembly 16 is heated is approximately near the melting temperature of the target material. For target materials such as CIG or CIGS, the furnace is typically heated to around 1450 degrees Fahrenheit (approximately 787 degrees Celsius). By heating the backing plate 12 and target 14 together, a strongly bonded alloy interface layer 21 is formed at the interface 20 between backing plate 12 and target 14 as shown in FIG. 2. Heating time depends on many variables, including the size and efficiency of the furnace and amount of target material.

In the case where a copper backing plate 12 and a CIG or CIGS target 14 are used, the copper of the backing plate and the Indium and Gallium of the target material at least partially diffuse and mix to form alloy interface layer 21 at the interface 20 that creates a strong physical bond between backing plate 12 and target 14.

Although the melting temperature of copper is approximately 1984 degrees Fahrenheit (approx 1085 degrees Celsius), the Copper atoms on the surface of the backing plate 12 diffuse with the Indium and Gallium atoms of the target material 14 to form a eutectic alloy that has a lower melting temperature. Therefore, rather than having a distinct border between the backing plate 12 and the target 14, there is a thin layer of alloy 21 between the two sections. Thickness of layer 21 depends on a number of variables, such as the speed at which target material 14 is cooled. In some embodiments, layer 21 is less than 1/16^{th} of an inch.

At step 104, the sputtering target assembly 16 is allowed to cool. Cooling may be passively performed, for example by turning the furnace off, or may be actively performed, for example by blowing air or some other gas onto the assembly, to quickly halt the alloying process between the materials, thereby controlling the thickness of the interface layer 21. In one embodiment, an inert gas, such as argon, is flushed through the furnace during cooling. The inert gas has the advantage of preventing any oxidation of the target or backing plate materials.

During the heating step, atoms from the backing plate 12 may migrate or diffuse well into the target 14, thereby significantly changing the proportions of the materials in the target 14. In order to prevent the backing plate 12 from being consumed by the target material, in one embodiment, an additional step of cooling the backing plate between several heating steps 103 or during the heating step 103 can be performed, thereby controlling the thickness of the alloy interface layer 21.

The thickness of the alloy interface layer 21 may also be controlled by the duration of the heating phase.

The backing plate 12 may be cooled during the heating step by a water channel 88 (FIG. 1B) in the form 10, by placing the backing plate 12 on a cooled surface, or by any other suitable means as will be apparent to the person skilled in the art.

In one embodiment, molten target material of target 14 is allowed to cool and solidify before heating the sputtering target assembly 16 to produce the alloy interface layer 21 at the interface 20. In another embodiment, the molten target material is allowed to cool and solidify in an inert atmosphere in order to prevent any oxidation of the backing plate or target material.

In one embodiment, the sputtering target assembly 16 may be removed from the form 10 prior to heating the target assembly.

In one embodiment, the backing plate 12 is heated to around the melting temperature of the target 14 before the target 14 is deposited on the backing plate 12.

In alternative embodiments, other heating temperatures may be used to form the alloy interface layer 21. For example, the person skilled in the art will readily recognize that some target materials of target 14 may form the alloy interface layer 21 with the backing plate material of backing plate 12 using a heating temperature that is above or below the melting temperature of the target material. Once target 16 is formed, target material 14 may be machined to any desired thickness or dimension. Tools used in the machining process should be made of a material that will not contaminate target material 14. For example, tools coated with a diamond layer are acceptable for many materials.

While furnace heating has been described, other heating methods may be employed, such as irradiative heating, electrical heating, and the like.

The mold or form 10 may be made in a shape to achieve a desired sputtering target shape. In FIGS. 1A-E, the form 10 is depicted as rounded in shape to produce a flat disk-shaped sputter target assembly as is common in the art. Any number of shapes are possible, however.

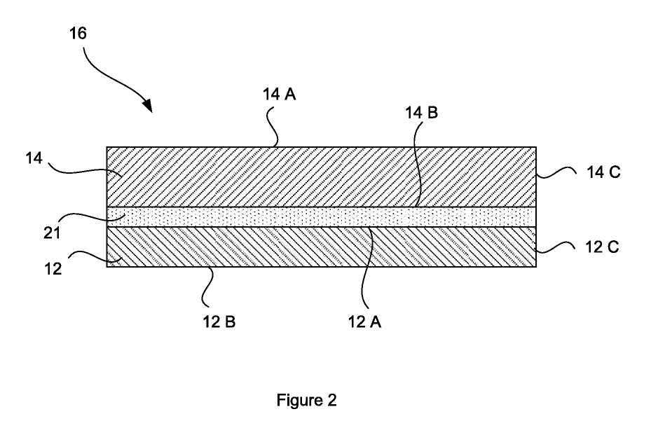

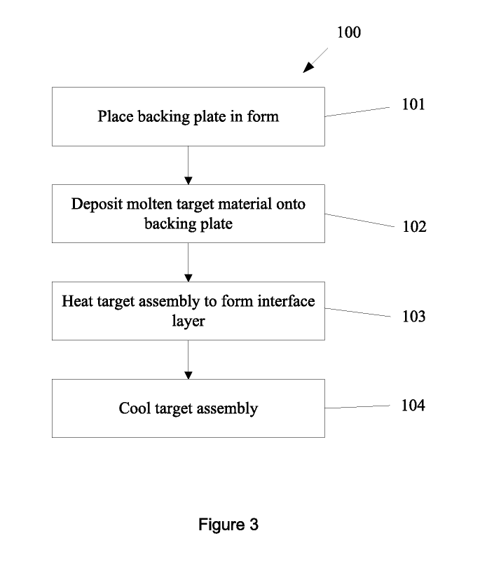

Turning now to FIGS. 4-5 and 7-8, another embodiment of a cylindrical sputtering target assembly is shown. Sputtering target assembly 40 can be used in a sputtering deposition machine to produce thin layers of a desired material on various substrates. The processing of sputtering target assembly 40 by method 100 produces the alloy interface layer 21 with a strong bond between the backing plate 12 and target 14 that resists and prevents separation or delamination during use in a sputtering deposition machine. It should be noted that targets made with the present process may be made in many different shapes and sizes, such as cones, disks squares, cylinders, rectangles etc.

Cylindrical sputtering target assembly 40 may include a target 50 formed of a target material that is deposited on a cylindrical backing support 60.

Backing support 60 can include an outer surface 62, an inner surface 64 and a bore 66 that extends through backing support 60.

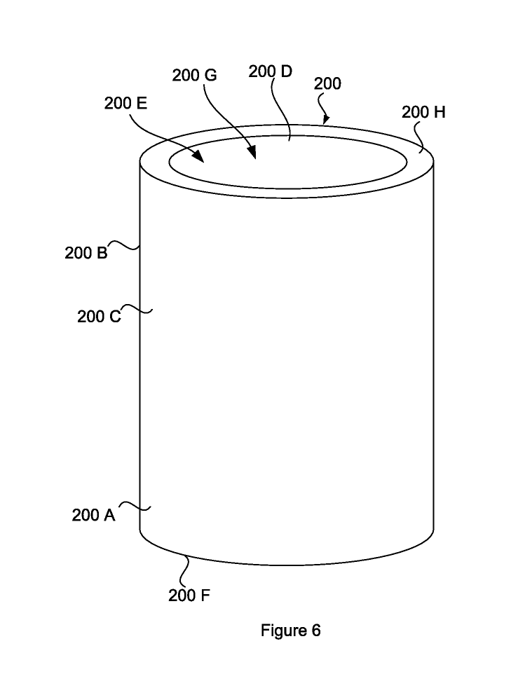

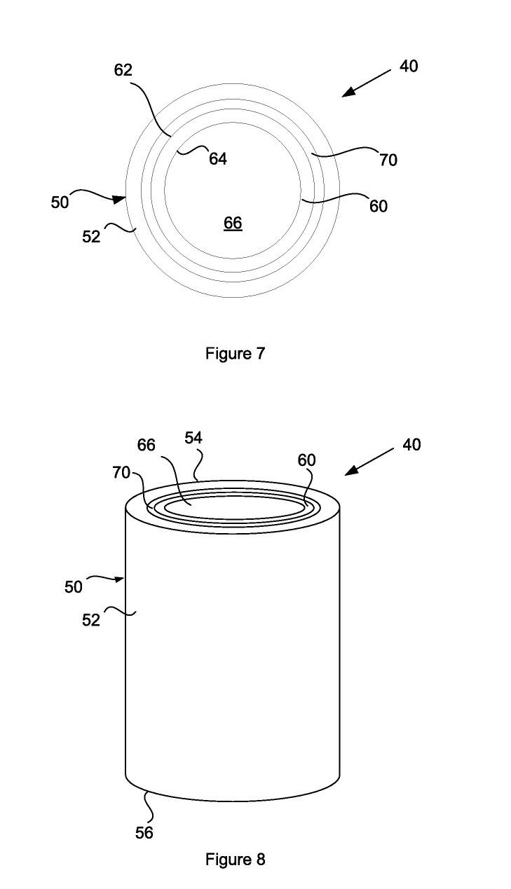

Target 50 can include an outer surface 52, an inner surface 53 and ends 54 and 56. Outer surface 62 of backing support 60 is in contact with inner surface 53 of target 50. After heating, an interface layer 70 (see FIGS. 7 and 8) is formed between outer surface 62 and inner surface 53.

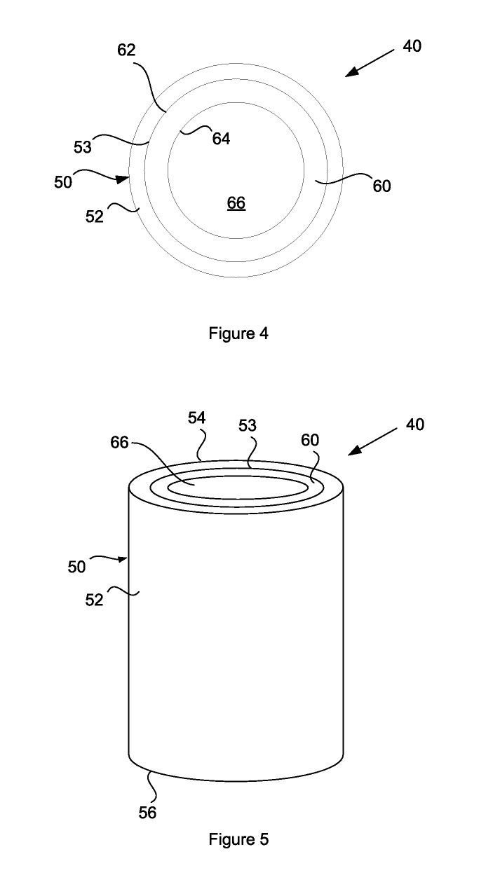

FIG. 6 shows a cylindrical form or mold 200 that may be used to produce sputtering target assembly 40. Mold 200 can include a base 200A from which side walls 200B extend upwardly. Side walls 200B have an outer surface 200C, an inner surface 200D and a top 200H. A bottom wall 200E is located above base 200A and between side walls 200B. A cavity 200G is defined between side walls 200B and the bottom wall 200E.

Mold 200 can be used with backing support 60 and target 50 to produce sputtering target assembly 40 having an interface layer 70 using the same process steps as shown in FIG. 3 for sputtering target assembly 16.

Referring back to FIGS. 4-5 and 7-8, sputtering target assembly 40 may be used as a rotating cylindrical target in a sputtering deposition machine. In an alternative embodiment, the present invention may be used in conjunction with technology related to liquid formed sputtering targets described in co-pending patent applications “Device and Method of Manufacturing Sputtering Targets”, U.S. application Ser. No. 11/533,999 filed Sep. 19, 2006, “Device and Method of Manufacturing Sputtering Targets”, U.S. Ser. No. 11/533,343 filed Sep. 19, 2006, and

“Device and Method of Manufacturing Sputtering Targets”, U.S. application Ser. No. 11/533,344 filed Sep. 19, 2006, the entire contents of each of these applications being specifically incorporated herein by reference.

Using the technology described in the foregoing patent applications, liquid target material is deposited on a substrate, such as backing support 60, and allowed to solidify. In these processes, the target material is deposited onto the substrate in a liquid stream while the substrate is moved relative to a source of the target material. The substrate and the solidified target material may then be placed in a furnace such as furnace 80, or otherwise heated, to raise the temperature of the assembly to approximately the melting point of the target material. Once at that temperature, the assembly may be cooled to produce the interface layer 70 between the backing support 60 and the target 50 material.

Although the description above contains many specifications, these should not be construed as limiting the scope of the invention but as merely providing illustrations of some of the embodiments of this invention. Thus, the scope of the invention should be determined by the appended claims and their legal equivalents rather than by the examples given.

What is claimed is:

1. A method of manufacturing a sputtering target assembly comprising, not all necessarily in the order shown:
A. depositing a target onto a substrate;
B. heating the substrate and the target to approximately a melting temperature of the target; and
C. cooling the substrate and the target such that an interface layer is formed between the substrate and the target.

2. The method of claim 1 wherein at least the target is cast in a form.

3. The method of claim 1 further including after depositing the target onto the substrate, allowing the target to solidify before the substrate and the target are heated.

4. The method of claim 1 wherein the target is deposited onto the substrate in a liquid stream while the substrate is moved relative to a source of a target material.

5. The method of claim 1 further including cooling the substrate during heating the substrate and target.

6. The method of claim 1 wherein heating the substrate and target is performed in an inert atmosphere.

7. The method of claim 1 wherein cooling the substrate and the target is performed in an inert atmosphere.

8. The method of claim 1 wherein the substrate and the target are rapidly cooled.

9. The method of claim 1 wherein the target is cooled at a rate that prevents segregation of the constituents of the target material.

10. The method of claim 1 wherein the substrate and/or the target are cooled at least in part by directing a gas on the substrate or the target.

11. The method of claim 1 wherein the substrate and/or the target are cooled at least in part by a liquid.

12. A method for manufacturing a sputtering target assembly comprising, not all necessarily in the order shown:
A. depositing a target onto a substrate; and
B. heating the target and the substrate to form an alloy interface layer at an interface of the target and the substrate, the alloy interface layer comprising at least a portion of the target and a portion of the substrate.

13. The method of claim 12 further comprising controlling the thickness of the alloy interface layer.

14. The method of claim 13 wherein controlling the thickness of the alloy interface layer includes cooling the substrate during the formation of the alloy interface layer.

15. The method of claim 12 wherein the heating is performed in an inert atmosphere.

16. The method of claim 12 further including:
A. placing the substrate into a mold;
B. depositing a molten target material onto the substrate in the mold to form the target.

17. The method of claim 16 further including cooling said molten target material prior to heating the target and substrate.

18. The method of claim 16 further including heating said substrate prior to depositing said molten target material.

19. The method of claim 12 wherein the step of heating the target and substrate includes heating at least the target to approximately a melting temperature of the target.

20. A sputtering target assembly including:
A. a backing plate having an outer surface and an inner surface;
B. a target having an outer surface and an inner surface; and
C. an interface layer formed between the outer surface of the substrate and the inner surface of the target, wherein the interface layer comprises an alloy of the substrate and the target.

21. The sputtering target assembly according to claim 20 wherein the backing plate is formed from copper or is copper coated.

22. The sputtering target assembly according to claim 20 wherein the target comprises at least one of copper, indium and gallium.

23. The sputtering target assembly according to claim 20 wherein the target comprises selenium.

24. The sputtering target assembly according to claim 20 wherein the interface layer is formed by heating the backing plate and the target material to a melting temperature of the target.

25. The method of claim 20 wherein the target is cooled at a rate that prevents segregation of the constituents of the target material.
